(19) United States
(12) Patent Application Publication
(10) Pub. No.: US 2026/0090483 A1
(43) Pub. Date: Mar. 26, 2026

(54) ELECTRONIC DEVICE

(71) Applicant: InnoLux Corporation, Miao-Li County (TW)

(72) Inventors: Jui-Jen YUEH, Miao-Li County (TW); Ti-Chung CHANG, Miao-Li County (TW)

(21) Appl. No.: 19/289,187

(22) Filed: Aug. 4, 2025

(30) Foreign Application Priority Data
Sep. 25, 2024 (CN) 202411340200.1

(51) Int. Cl. H01L 23/498; H01L 23/538; H01L 25/03

(52) U.S. Cl. CPC H10W 90/701; H10W 70/611; H10W 90/00; H10W 90/401

(57) ABSTRACT

An electronic device includes a substrate, a first circuit layer, a first semiconductor die, a second circuit layer, and first conductive elements. The first circuit layer includes first pads. The second circuit layer includes second pads. The first conductive elements are between the first circuit layer and the second circuit layer. Each of the first conductive elements is electrically connected to one of the first pads and one of the second pads. Each of the first conductive elements includes a first portion adjacent to the first pad, a second portion adjacent to the second pad, and a middle portion between the first portion and the second portion. The first conductive elements include first-type conductive elements and second-type conductive elements. Each of the first-type conductive elements has a maximum width at the middle portion, and each of second-type conductive elements has a maximum width at the first portion.

### CROSS REFERENCE TO RELATED APPLICATIONS

This application claims the benefit of China Application No. 202411340200.1, filed Sep. 25, 2024, the entirety of which is incorporated by reference herein.

### BACKGROUND

### Technical Field

The present disclosure is related to an electronic device, and in particular it is related to a connection structure of an electronic device.

### Description of the Related Art

Packaging technology can increase the integration density of electronic components (e.g., transistors, diodes, resistors, capacitors, etc.) in a given area. This has been widely used in the production and manufacturing of electronic devices in recent years. As the packaging size of semiconductors becomes smaller, the reliability requirements for chip manufacturing and packaging technology are also getting higher.

However, the packaging structure has many integration structures of heterogeneous material interfaces (for example, the interface between the redistribution layer (RDL) and the conductive pad, the interface between the under bump metallurgy (UBM) and the conductive pad, etc.). The interfaces of heterogeneous materials are often prone to delamination or peeling due to the presence of high degrees of stress. Furthermore, the connection elements (e.g., solder balls) used in the bonding process can easily become displaced or deformed during the reflow process due to the different coefficients of thermal expansion of the bonding objects. When displacement or deformation is too great, the performance and reliability of the connection structure will be affected.

Based on the above, developing a structural design for improving the reliability of a packaging structure of an electronic device (e.g., improving the stability or strength of a connection structure) is still one of the current research topics in the industry.

### SUMMARY

In accordance with some embodiments of the present disclosure, an electronic device is provided. The electronic device includes a substrate, a first circuit layer, a first semiconductor die, a second circuit layer, and a plurality of first conductive elements. The first circuit layer is disposed on the substrate and includes a plurality of first pads. The first semiconductor die is disposed on the first circuit layer. The second circuit layer is electrically connected to the first semiconductor die, and is disposed between the first circuit layer and the first semiconductor die. The second circuit layer includes a plurality of second pads. The plurality of first conductive elements are disposed between the first circuit layer and the second circuit layer. Each of the plurality of first conductive elements is electrically connected to one of the plurality of first pads and one of the plurality of second pads. Each of the plurality of first conductive elements includes a first portion adjacent to one of the plurality of first pads, a second portion adjacent to one of the plurality of second pads, and a middle portion between the first portion and the second portion. Furthermore, the plurality of first conductive elements include a plurality of first-type conductive elements and a plurality of second-type conductive elements. Each of the plurality of first-type conductive elements has a maximum width at the middle portion, and each of the plurality of second-type conductive elements has a maximum width at the first portion.

A detailed description is given in the following embodiments with reference to the accompanying drawings.

### BRIEF DESCRIPTION OF THE DRAWINGS

The disclosure may be more fully understood by reading the subsequent detailed description and examples with references made to the accompanying drawings, wherein:

FIG. 1 is a partial cross-sectional diagram of an electronic device in accordance with some embodiments of the present disclosure;

FIG. 2A is an enlarged schematic diagram of area A1 in FIG. 1 in accordance with some embodiments of the present disclosure;

FIG. 2B is an enlarged schematic diagram of area A2 in FIG. 1 in accordance with some embodiments of the present disclosure;

FIG. 3 is a partial cross-sectional diagram of an electronic device in accordance with some embodiments of the present disclosure;

FIG. 4A is an enlarged schematic diagram of area A1 in FIG. 1 in accordance with some embodiments of the present disclosure;

FIG. 4B is an enlarged schematic diagram of area A2 in FIG. 1 in accordance with some embodiments of the present disclosure;

FIG. 5 is a partial cross-sectional diagram of some component of an electronic device in accordance with some embodiments of the present disclosure;

FIG. 6A is an enlarged schematic diagram of area A3 in FIG. 5 in accordance with some embodiments of the present disclosure;

FIG. 6B is an enlarged schematic diagram of area A4 in FIG. 5 in accordance with some embodiments of the present disclosure;

FIG. 7 is a cross-sectional diagram of an electronic device in accordance with some embodiments of the present disclosure;

FIG. 8 is a cross-sectional diagram of an electronic device in accordance with some embodiments of the present disclosure.

### DETAILED DESCRIPTION

The electronic device and the method of manufacturing the electronic device according to the present disclosure are described in detail in the following description. It should be understood that in the following detailed description, for purposes of explanation, numerous specific details and embodiments are set forth in order to provide a thorough understanding of the present disclosure. The elements and configurations described in the following detailed description are set forth in order to clearly describe the present disclosure. These embodiments are used merely for the purpose of illustration, and the present disclosure is not limited thereto. In addition, different embodiments may use like and/or corresponding numerals to denote like and/or corresponding elements in order to clearly describe the present disclosure. However, the use of like and/or corresponding numerals of different embodiments does not suggest any correlation between different embodiments.

It should be understood that relative expressions may be used in the embodiments. For example, “lower”, “bottom”, “higher” or “top” are used to describe the position of one element relative to another. It should be appreciated that if a device is flipped upside down, an element that is “lower” will become an element that is “higher”. The present disclosure can be understood by referring to the following detailed description in connection with the accompanying drawings. The drawings are also regarded as part of the description of the present disclosure. It should be understood that the drawings of the present disclosure may be not drawn to scale. In fact, the size of the elements may be arbitrarily enlarged or reduced to clearly represent the features of the present disclosure.

Furthermore, the expression “a first material layer is disposed on or over a second material layer” may indicate that the first material layer is in direct contact with the second material layer, or it may indicate that the first material layer is in indirect contact with the second material layer. In the situation where the first material layer is in indirect contact with the second material layer, there may be one or more intermediate layers between the first material layer and the second material layer. However, the expression “the first material layer is directly disposed on or over the second material layer” means that the first material layer is in direct contact with the second material layer, and there is no intermediate element or layer between the first material layer and the second material layer.

Moreover, it should be understood that the ordinal numbers used in the specification and claims, such as the terms “first”, “second”, etc., are used to modify an element, which itself does not mean and represent that the element (or elements) has any previous ordinal number, and does not mean the order of a certain element and another element, or the order in the manufacturing method. The use of these ordinal numbers is to make an element with a certain name can be clearly distinguished from another element with the same name. Claims and the specification may not use the same terms. For example, the first element in the specification may refer to the second element in the claims.

In accordance with the embodiments of the present disclosure, regarding the terms such as “connected to”, “interconnected with”, etc. referring to bonding and connection, unless specifically defined, these terms mean that two structures are in direct contact or two structures are not in direct contact, and other structures are provided to be disposed between the two structures. The terms for bonding and connecting may also include the case where both structures are movable or both structures are fixed. In addition, the term “electrically connected to” or “coupled to” may include any direct or indirect electrical connection means.

In the following descriptions, terms “about”, “substantially” and “approximately” typically mean+/−10% of the stated value, or typically +/−5% of the stated value, or typically +/−3% of the stated value, or typically +/−2% of the stated value, or typically +/−1% of the stated value or typically +/−0.5% of the stated value. The expression “in a range from the first value to the second value” or “between the first value and the second value” means that the range includes the first value, the second value, and other values in between. Moreover, certain errors may exist between any two values or directions used for comparison. If the first value is equal to the second value, it implies that there may be an error of about 10% between the first value and the second value; if the first direction is perpendicular to the second direction, the angle between the first direction and the second direction may be between 80 degrees and 100 degrees; if the first direction is parallel to the second direction, the angle between the first direction and the second direction may be between 0 degrees and 10 degrees.

In accordance with the embodiments of the present disclosure, a scanning electron microscope (SEM), an optical microscope (OM), a film thickness profiler (α-step), an ellipsometer or another suitable method may be used to measure the width, thickness, or heigh of each element, or spacing or distance between elements. Specifically, in accordance with some embodiments, a scanning electron microscope can be used to obtain a cross-sectional image including the elements to be measured, and measure the width, thickness, or heigh of each element, or spacing or distance between elements.

It should be understood that in the following embodiments, without departing from the spirit of the present disclosure, the features in several different embodiments can be replaced, recombined, and mixed to complete another embodiment. The features between the various embodiments can be mixed and matched arbitrarily as long as they do not violate or conflict the spirit of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

In accordance with some embodiment of the present disclosure, an electronic device is provided that includes a connection structure configured in a specific manner (for example, including first-type conductive elements and second-type conductive elements disposed between circuit layers). With the combination and configuration of conductive elements with different structural types, the connection structure can have the dual functions of absorbing stress and resisting stress, thereby alleviating problems such as peeling, breaking, or excessive displacement or deformation of the connection structure. The structural strength and reliability of the electronic device therefore can be improved.

In accordance with the embodiments of the present disclosure, the electronic device can be applied to a power module, a semiconductor packaging device, a display device, a backlight device, an antenna device, a touch device, a sensing device, a wearable device, a vehicle device, a battery device or a tiled device, but it is not limited thereto. The electronic device may be a bendable or flexible electronic device. The display device may be a non-self-luminous display device or a self-luminous display device. The antenna device may be a liquid-crystal type antenna device or a non-liquid-crystal type antenna device. The sensing device may be a sensing device that senses capacitance, light, heat energy, or ultrasound, but it is not limited thereto. Furthermore, the electronic device may include, for example, liquid crystal, quantum dot (QD), fluorescence, phosphor, another suitable material or a combination thereof. The electronic device may include electronic components, which may include passive components and active components, such as capacitors, resistors, inductors, diodes, transistors, etc. The diode may include a light-emitting diode or a photodiode. The light-emitting diode may include, for example, an organic light-emitting diode (OLED), a mini light-emitting diode (mini LED), a micro LED, or a quantum dot light-emitting diode (quantum dot LED), but it is not limited thereto. In accordance with some embodiments, the electronic device may include a panel and/or a backlight module. The panel may include, for example, a liquid-crystal panel or other self-luminous panels, but it is not limited thereto. The tiled device may be, for example, a display tiled device or an antenna tiled device, but it is not limited thereto. It should be understood that the electronic device can be any combination of the above, but it is not limited thereto.

In accordance with the embodiments of the present disclosure, the structure of the provided electronic device can be applied, for example, to a wafer-level package (WLP) or panel-level package (PLP) process, and the chip first process or the chip last/RDL first process may be used, which will be explained in further detail below. Furthermore, in accordance with the embodiments of the present disclosure, the packaging structure of the electronic device may include System on Chip (SoC), System in Package (SiP), Chip on Wafer on Substrate (CoWoS) packaging, System on Integrated Chip (SoIC), Antenna in Package (AiP), Co-Packaged Optics (CPO), Micro Electro Mechanical System (MEMS) or a combination thereof, but it is not limited thereto.

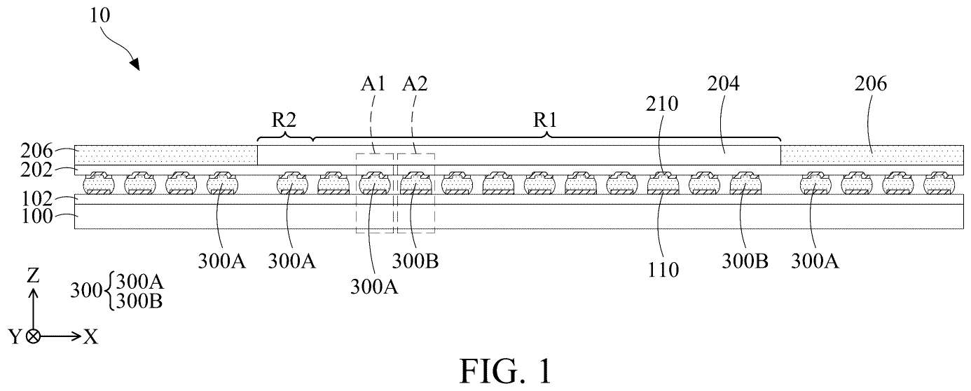

Please refer to FIG. 1, which is a partial cross-sectional diagram of an electronic device 10 in accordance with some embodiments of the present disclosure. It should be understood that, for the sake of clarity, some elements of the electronic device 10 may be omitted in the drawings, and only some elements are schematically illustrated. In accordance with some embodiments, additional features may be added to the electronic device 10 described below. In accordance with some other embodiments, some features of the electronic device 10 described below may be replaced or omitted.

As shown in FIG. 1, the electronic device 10 may include a substrate 100, a first circuit layer 102, a first semiconductor die 204, a second circuit layer 202, and a plurality of first conductive elements 300.

The substrate 100 may include a rigid substrate, a flexible substrate, or a combination thereof. In accordance with some embodiments, the material of the substrate 100 may include glass, quartz, sapphire, ceramic, glass fiber reinforced plastics, Bismaleimide Triazine Resin (BT resin), Ajinomoto Build-up Film (ABF), liquid-crystal polymer (LCP), polyimide (PI), polycarbonate (PC), epoxy resin, polyethylene terephthalate (PET), polypropylene (PP), polydimethylsiloxane (PDMS), another suitable material or a combination thereof, but it is not limited thereto.

The first circuit layer 102 may be disposed on the substrate 100 and include a plurality of first pads 110. The first pads 110 may be disposed on the top of the first circuit layer 102, and the first pads 110 may be electrically connected to conductive elements (not illustrated) in the first circuit layer 102. In accordance with some embodiments, the substrate 100, the first circuit layer 102, and the first pads 110 may serve as a packaging substrate, but it is not limited thereto.

The first circuit layer 102 may have one or more multi-layer structures, and may include one or more dielectric layers and patterned conductive layers. In accordance with some embodiments, the first circuit layer 102 may also serve as a redistribution layer (RDL). In accordance with some embodiments, the material of the dielectric layer of the first circuit layer 102 may include an organic dielectric material, such as polybenzoxazole (PBO), perfluoroalkoxy alkane (PFA), polytetrafluoroethylene (PTFE), fluorinated ethylene propylene (FEP), Ajinomoto Build-up Film (ABF), flame resistant glass fiber (FR4), glass fiber resin composite material, polyimide, benzocyclobutene (BCB), epoxy resin, another suitable dielectric material or a combination thereof, but it is not limited thereto. In accordance with some embodiments, the material of the patterned conductive layer of the first circuit layer 102 may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material or a combination thereof, but it is not limited thereto. Furthermore, in accordance with some embodiments, the first substrate 100 and the first circuit layer 102 may be a printed circuit board (PCB), but it is not limited thereto.

In addition, the first pad 110 may include a conductive material, such as a metallic conductive material. In accordance with some embodiments, the first pad 110 may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material, or a combination thereof, but it is not limited thereto.

The first semiconductor die 204 may be disposed on the first circuit layer 102. The second circuit layer 202 may be electrically connected to the first semiconductor die 204. The second circuit layer 202 may be disposed between the first circuit layer 102 and the first semiconductor die 204. The second circuit layer 202 may include a plurality of second pads 210. In the normal direction of the substrate 100 (e.g., the Z direction in the drawings), parts of the second pads 210 may overlap with the first semiconductor die 204. The second pads 210 may be electrically connected to conductive elements (not illustrated) in the second circuit layer 202. In accordance with some embodiments, the second circuit layer 202 may serve as a redistribution layer (RDL), the second pads 210 may serve as an under-bump metallurgy (UBM), and the second pads 210 may be electrically connected to the IC signal line of the second circuit layer 202, but it is not limited thereto.

The first semiconductor die 204 may include a known-good die (KGD), an integrated circuit chip (IC), or another suitable electronic component, but it is not limited thereto. Specifically, in accordance with some embodiments, the first semiconductor die 204 may include a system on chip, a dynamic random access memory, a high bandwidth memory, a photonic integrated circuit, an application specific integrated circuit, or another logic integrated circuit.

The second circuit layer 202 may have one or more dielectric layers and patterned conductive layers. In accordance with some embodiments, the dielectric layer of the second circuit layer 202 may include a polymer dielectric insulating material, such as polybenzoxazole (PBO), polyimide, benzocyclobutene (BCB), another suitable polymer dielectric material or a combination thereof, but it is not limited thereto. In accordance with some other embodiments, the dielectric layer of the second circuit layer 202 may include silicon nitride, silicon oxide, silicon oxynitride, phosphosilicate glass (PSG), borosilicate glass (BSG), boron-doped phosphosilicate glass (BPSG), another suitable dielectric material or a combination thereof, but it is not limited thereto. In accordance with some embodiments, the material of the patterned conductive layer of the second circuit layer 202 may include copper (Cu), titanium (Ti), aluminum (Al), tungsten (W), silver (Ag), gold (Au), tin (Sn), molybdenum (Mo), chromium (Cr), nickel (Ni), platinum (Pt), palladium (Pd), alloys of the aforementioned metals, another suitable conductive material or a combination thereof, but it is not limited thereto.

The material of the second pad 210 may be the same as or similar to the material of the first pad 110, and thus will not be repeated here.

As shown in FIG. 1, in accordance with some embodiments, the electronic device 10 may further include an encapsulating layer 206. The encapsulating layer 206 may surround the first semiconductor die 204, and at least one of the second pads 210 overlaps with the encapsulating layer 206. In accordance with some embodiments, in the normal direction of the substrate 100 (e.g., the Z direction in the drawings), parts of the second pads 210 may overlap with the encapsulation layer 206. Furthermore, in accordance with some embodiments, a portion of the second circuit layer 202 may be disposed between the encapsulating layer 206 and the second pad 210. The encapsulating layer 206 may contact the first semiconductor die 204 and the second circuit layer 202. In accordance with some embodiments, the encapsulation layer 206 may cover the side surfaces and the top surface (not illustrated) of the first semiconductor die 204. The encapsulation layer 206 can reduce the impact of water and oxygen in the external environment on the first semiconductor die 204. In accordance with some embodiments, the encapsulation layer 206 may include a molding compound, an epoxy, another suitable encapsulation material, or a combination thereof, but it is not limited thereto.

In addition, as shown in FIG. 1, the first conductive elements 300 may be disposed between the first circuit layer 102 and the second circuit layer 202. Each of the first conductive elements 300 may be electrically connected to the first pad 110 and the second pad 210. The first conductive element 300 may serve as a connection structure between the first pad 110 and the second pad 210. The first semiconductor die 204 may be electrically connected to the first circuit layer 102 on the substrate 100 through the first conductive element 300.

In accordance with some embodiments, the first conductive element 300 may include tin, silver, lead-free tin, copper, nickel, gold, another suitable material or a combination thereof, but it is not limited thereto. In accordance with some embodiments, the first conductive element 300 may be bonded to the first pad 110 and the second pad 210 by a reflow process, a fusion bonding process, a hybrid bonding process, a metal-to-metal bonding process, another suitable method or a combination thereof, thereby bonding the first semiconductor die 204 to the substrate 100.

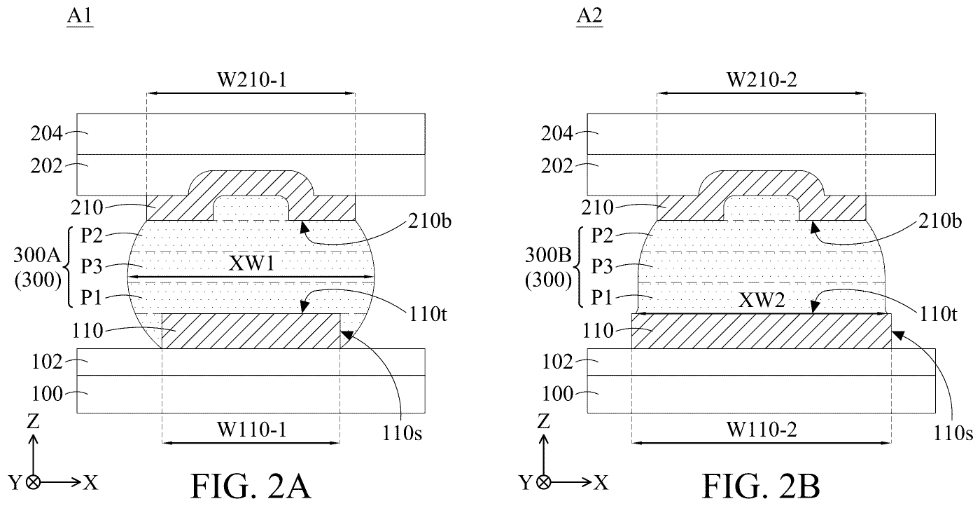

In particular, the first conductive elements 300 may include a plurality of first-type conductive elements 300A and a plurality of second-type conductive elements 300B. The first-type conductive element 300A and the second-type conductive element 300B may have different structural aspects. Please refer to FIG. 2A and FIG. 2B, which respectively are enlarged schematic diagrams of area A1 and area A2 in FIG. 1 in accordance with some embodiments of the present disclosure.

As shown in FIG. 2A and FIG. 2B, the first conductive element 300 (the first-type conductive element 300A and the second-type conductive element 300B) each includes a first portion P1 adjacent to the first pad 110, a second portion P2 adjacent to the second pad 210, and a middle portion P3 between the first portion P1 and the second portion P2. In accordance with some embodiments, the first portion P1, the second portion P2, and the middle portion P3 may be three equal parts of the first conductive element 300 between the top surface 110t of the first pad 110 and the bottom surface 210b of the second pad 210. Moreover, in the normal direction of the substrate 100 (e.g., the Z direction in the drawing), the first portion P1, the second portion P2, and the third portion P3 have the same thickness.

Specifically, the first-type conductive element 300A has a maximum width XW1 in the middle portion P3, and the second-type conductive element 300B has a maximum width XW2 in the first portion P1. Since the maximum width XW1 of the first-type conductive element 300A is located in the middle portion P3, it can provide better structural flexibility. Since the maximum width XW2 of the second-type conductive element 300B is located closer to the first portion P1 of the first pad 110, it can provide better structural stability. In addition, as shown in FIG. 2B, in accordance with some embodiments, the maximum width XW2 of the second-type conductive element 300B may be located at an interface between the first portion P1 and the first pad 110. That is, the maximum width XW2 of the second-type conductive element 300B may be located at the bottommost portion.

In accordance with some embodiments, the aforementioned maximum width XW1 refers to the maximum width of the first-type conductive element 300A in the direction perpendicular to the normal direction of the substrate 100 (e.g., the X direction in the drawing); and the aforementioned maximum width XW2 refers to the maximum width of the second-type conductive element 300B in the direction perpendicular to the normal direction of the substrate 100 (e.g., the X direction in the drawing).

It is noted that, with the combination and configuration of the first conductive elements 300 with different structural types and functions, the problem of excessive stress concentration on the joint surface during bonding, which may cause the first pad 110 and the second pad 210 to peel off or break, can be alleviated. The problem of excessive position displacement or excessive deformation of the first pad 110 and the second pad 210, which may affect the quality of electrical connection, can also be alleviated. Therefore, the structural strength and reliability of the electronic device can be improved.

Please refer to FIG. 1 again. In accordance with some embodiments, the first semiconductor die 204 has a main region R1 and an edge region R2, and the first-type conductive elements 300A and the second-type conductive elements 300B may be arranged alternately under the main region R1. In accordance with some embodiments, the boundary between the main region R1 and the edge region R2 of the first semiconductor die 204 corresponds to the position where the second-type conductive element 300B starts to be disposed. Specifically, under the main region R1, at least some of the first-type conductive elements 300A and the second-type conductive elements 300B are arranged alternately, some of the first-type conductive elements 300A may be arranged repeatedly in succession, and some of the second-type conductive elements 300B may also be arranged repeatedly in succession. As shown in FIG. 1, in accordance with some embodiments, a first-type conductive element 300A, a second-type conductive element 300B, a first-type conductive element 300A, a second-type conductive element 300B . . . are arranged sequentially, but the present disclosure is not limited thereto. In accordance with different embodiments, the first-type conductive elements 300A and the second-type conductive elements 300B may be arranged in other suitable sequences, as long as some of the first-type conductive elements 300A and the second-type conductive elements 300B are arranged alternately.

In addition, in accordance with some embodiments, a ratio of the number of first-type conductive elements 300A to the number of second-type conductive elements 300B under the main region R1 may be greater than or equal to 1 and less than or equal to 5 (i.e. 1≤the number of first-type conductive elements 300A/the number of second-type conductive elements 300B≤5), for example, may be 1, 2, 3, 4 or 5. In accordance with some embodiments, the number of the first-type conductive elements 300A may be greater than the number of the second-type conductive elements 300B under the main region R1.

It is noted that with the configuration of the first-type conductive elements 300A and the second-type conductive elements 300B in an appropriate ratio, the bonding structure can be adapted to various products with different pad pitches or resolutions while maintaining the stability of the bonding structure.

On the other hand, in accordance with some embodiments, the first conductive element 300 overlapping the encapsulation layer 206 substantially has the structure of the first-type conductive element 300A, but the present disclosure is not limited thereto.

Please continue to refer to FIG. 2A and FIG. 2B. In accordance with some embodiments, the first-type conductive element 300A may be in contact with the side surface 110s of the first pad 110. In detail, the first conductive element 300 contacts at least a portion of at least one side surface 110s of the first pad 110. In accordance with some embodiments, the second-type conductive element 300B contacts the top surface 110t of the first pad 110, but does not contact the side surface 110s of the first pad 110.

It should be noted that by designing that at least a portion of the side surface 110s of the first pad 110 is covered by the first-type conductive element 300A, the impedance between the first pad 110 and the first-type conductive element 300A can be reduced, and the bonding strength between the two can be increased or the conductivity can be improved.

Furthermore, the first-type conductive element 300A contacts the first pad 110 and the second pad 210. The first pad 110 contacting the first-type conductive element 300A has a width W110-1, and the second pad 210 contacting the first-type conductive element 300A has a width W210-1. The second-type conductive element 300B contacts the first pad 110 and the second pad 210. The first pad 110 contacting the second-type conductive element 300B has a width W110-2, and the second pad 210 contacting the second-type conductive element 300B has a width W210-2. In accordance with some embodiments, a ratio of the width W110-1 to the width W210-1 is smaller than a ratio of the width W110-2 to the width W210-2 (i.e. width W110-1/width W210-1<width W110-2/width W210-2).

Moreover, in accordance with some embodiments, the ratio of the width W110-1 to the width W210-1 may be greater than or equal to 0.7 and less than or equal to 1.2 (i.e. 0.7≤width W110-1/width W210-1≤1.2), for example, may be 0.7, 0.8, 0.9, 1, 1.1 or 1.2. In accordance with some embodiments, the ratio of the width W110-2 to the width W210-2 may be greater than or equal to 1.3 and less than or equal to 3 (i.e. 1.3≤width W110-2/width W210-2<3), for example, may be 1.3, 1.4, 1.5, 1.6, 1.7, 1.8, 1.9, 2, 2.1, 2.2, 2.3, 2.4, 2.5, 2.6, 2.7, 2.8, 2.9 or 3. Furthermore, in accordance with some embodiments, the width W110-1 of the first pad 110 contacting the first-type conductive element 300A is smaller than the width W110-2 of the first pad 110 contacting the second-type conductive element 300B.

In accordance with some embodiments, the aforementioned width W110-1 and width W110-2 refer to the maximum widths of the first pad 110 in the direction perpendicular to the normal direction of the substrate 100 (e.g., the X direction in the drawing); and the aforementioned width W210-1 and width W210-2 refer to the maximum widths of the second pad 210 in the direction perpendicular to the normal direction of the substrate 100 (e.g., the X direction in the drawing).

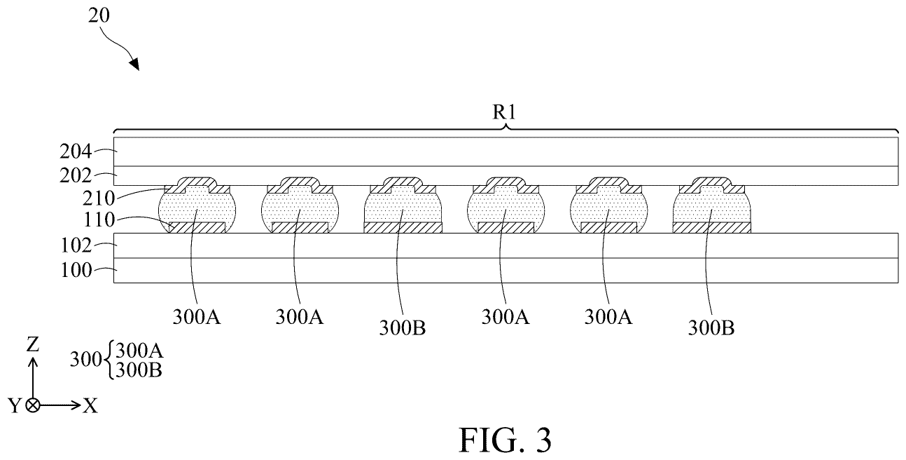

Next, please refer to FIG. 3, which is a partial cross-sectional diagram of an electronic device 20 in accordance with some other embodiments of the present disclosure. It should be understood that, for the sake of clarity, some components of the electronic device 20 may be omitted in the drawings, and only some components are schematically illustrated. In accordance with some embodiments, additional features may be added to the electronic device 20 described below. In accordance with some other embodiments, some features of the electronic device 20 described below may be replaced or omitted. In addition, the components or elements that are the same or similar to those mentioned above will be represented by the same or similar numbers below, and their materials and functions are the same or similar as those mentioned above, and thus will not be repeated in the following description.

As described above, under the main region R1, at least some of the first-type conductive elements 300A and the second-type conductive elements 300B are arranged alternately. Some of the first-type conductive elements 300A may be arranged repeatedly in succession, and some of the second-type conductive elements 300B may also be arranged repeatedly in succession. As shown in FIG. 3, in this embodiment, the first conductive elements 300 may be arranged successively in the order of first-type conductive element 300A, first-type conductive element 300A, second-type conductive element 300B, first-type conductive element 300A, first-type conductive element 300A, second-type conductive element 300B. In this embodiment, the ratio of the number of first-type conductive elements 300A to the number of second-type conductive elements 300B under the main region R1 also may be greater than or equal to 1 and less than or equal to 5 (i.e. 1≤the number of first-type conductive elements 300A/the number of second-type conductive elements 300B≤5), for example, may be 1, 2, 3, 4 or 5.

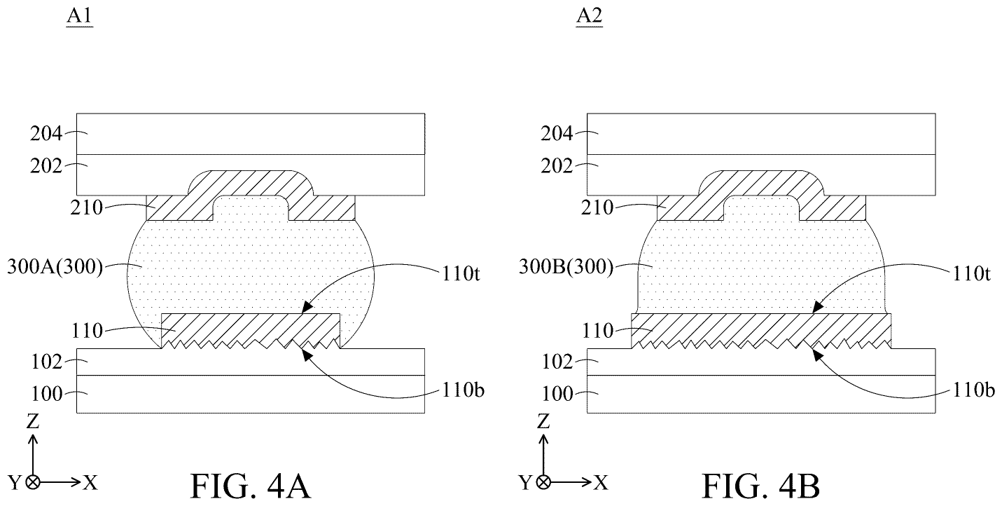

Please refer to FIG. 4A and FIG. 4B, which respectively are enlarged schematic diagrams of area A1 and area A2 in FIG. 1 in accordance with some other embodiments of the present disclosure.

As shown in FIG. 4A and FIG. 4B, in accordance with some embodiments, the first pad 110 has a top surface 110t and a bottom surface 110b opposite to the top surface 110t, and the roughness of the bottom surface 110b is greater than the roughness of the top surface 110t. Specifically, the first pad 110 in contact with the first-type conductive element 300A and the first pad 110 in contact with the second-type conductive element 300B may have the bottom surfaces 110b with relatively large roughness. In accordance with some embodiments, the roughness (Ra) of the bottom surface 110b of the first pad 110 may be between 0.1 μm and 10 μm, for example, may be 0.5 μm, 1 μm, 1.5 μm, 2 μm, 2.5 μm, 3 μm, 3.5 μm, 4 μm, 4.5 μm, 5 μm, 5.5 μm, 6 μm, 6.5 μm, 7 μm, 7.5 μm, 8 μm, 8.5 μm, 9 μm or 9.5 μm, but it is not limited thereto. When the roughness of the bottom surface 110b of the first pad 110 is greater than the roughness of the top surface 110t, the adhesion between the first pad 110 and the first circuit layer 102 or the substrate 100 can be improved.

In accordance with the embodiments of the present disclosure, the roughness can be determined by using a scanning electron microscope (SEM) or a transmission electron microscope (TEM) to observe the surface undulations at an appropriate magnification. Moreover, the surface undulations are compared in a unit length (for example, 50 μm). Herein, “appropriate magnification” means that at least 10 undulating peaks and valleys can be observed on at least one surface under the field of view of this magnification.

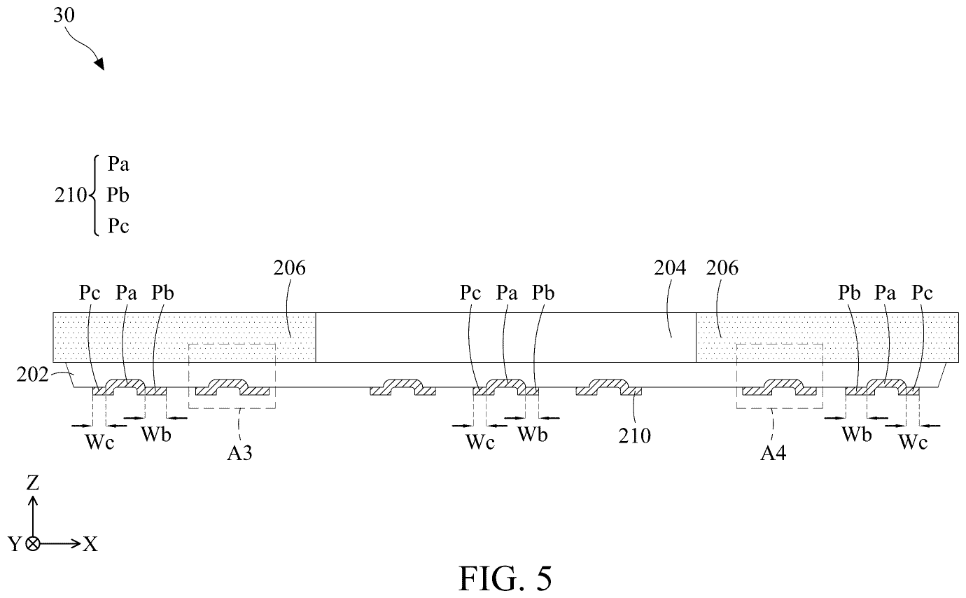

Please refer to FIG. 5, which is a partial cross-sectional diagram of some component of an electronic device 30 in accordance with some other embodiments of the present disclosure. It should be understood that for the sake of clarity, only the second circuit layer 202, the first semiconductor die 204, the encapsulating layer 206 and the second pads 210 of the electronic device 30 are shown in the figure.

As shown in FIG. 5, in a cross-sectional view, the second pad 210 may have a recessed portion (corresponding to the portion Pa described below) and extension portions located on both sides of the recessed portion (corresponding to the portion Pb and the portion Pc described below). In accordance with some embodiments, the two extension portions of the second pad 210 overlapping the encapsulation layer 206 may have different widths. Specifically, in accordance with some embodiments, in a cross-sectional view, the second pad 210 overlapping the encapsulating layer 206 may include a portion Pa, a portion Pb, and a portion Pc. The portion Pa is in contact with the conductive layer (not illustrated) of the second circuit layer 202, the portion Pb is connected to a side of the portion Pa adjacent to the first semiconductor die 204, and the portion Pc is connected to the other side of the portion Pa away from the first semiconductor die 204. Moreover, a width Wb of the portion Pb is greater than a width Wc of the portion Pc (i.e. width Wb>width Wc). In other words, the width of the extension portion of the second pad 210 overlapping the encapsulating layer 206 on the side closer to the first semiconductor die 204 may be greater than the width of the extension portion of the second pad 210 on the side farther from the first semiconductor die 204. Furthermore, in accordance with some embodiments, a ratio of the width Wc of portion Pc to the width Wb of portion Pb may be greater than or equal to 0.6 and less than or equal to 0.9 (i.e. 0.6≤width Wc/width Wb≤0.9), for example, may be 0.6, 0.7, 0.8 or 0.9.

In addition, as mentioned above, parts of the second pads 210 may overlap with the first semiconductor die 204. In accordance with some embodiments, two extension portions of the second pad 210 overlapping the first semiconductor die 204 may have substantially the same width. Specifically, in accordance with some embodiments, the second pad 210 overlapping the first semiconductor die 204 includes a portion Pa in contact with the conductive layer (not illustrated) of the second circuit layer 202, a portion Pb connected to one side of the portion Pa, and a portion Pc connected to the other side of the portion Pa, and a ratio of the width Wb of the portion Pb to the width Wc of the portion Pc may be greater than or equal to 0.9 and less than or equal to 1.1 (i.e. 0.9≤width Wc/width Wb≤1.1), for example, may be 0.9, 1 or 1.1.

It should be noted that since the thermal expansion coefficients of the first semiconductor die 204 and the encapsulating layer 206 are different (the thermal expansion coefficient of the encapsulating layer 206 is greater than the thermal expansion coefficient of the first semiconductor die 204), the position of parts of the second pads 210 (for example, the first semiconductor die 204 overlapping with the encapsulating layer 206) may be greatly displaced during the bonding process (for example, the reflow soldering process), which may cause misalignment with the first pad 110 on the opposite side. The asymmetric design of the second pads 210 overlapping the encapsulating layer 206 can reduce the influence of the difference in thermal expansion coefficients on the bonding between the second pad 210 and the first conductive element 300 and the first pad 110, thereby improving the stability of the bonding structure.

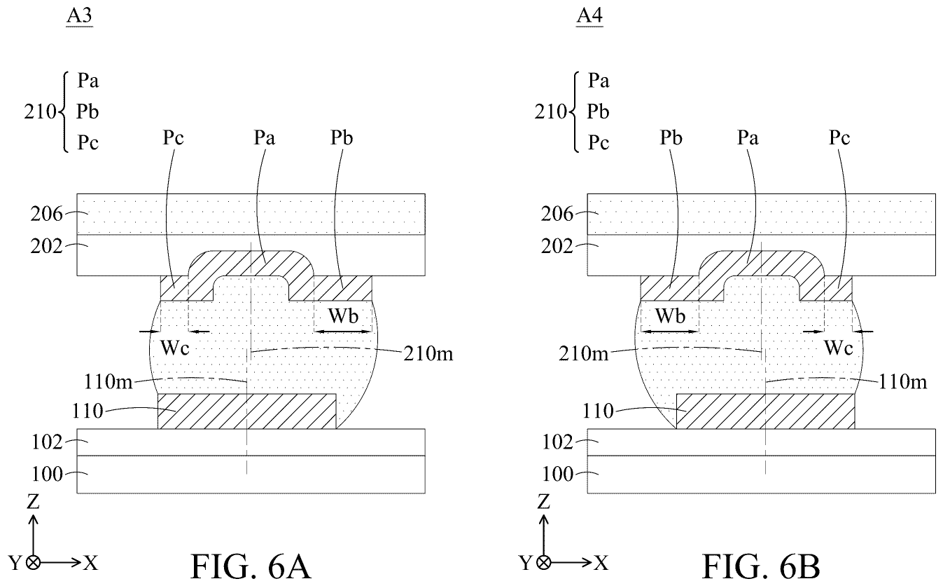

Further, please refer to FIG. 6A and FIG. 6B, which respectively are enlarged schematic diagrams of area A3 and area A4 in FIG. 5 in accordance with some embodiments of the present disclosure. In detail, FIG. 6A and FIG. 6B respectively show the cross-sectional diagrams of the structures in the area A3 and the area A4 corresponding to FIG. 5 after the first conductive element 300 is bonded to the first pad 110.

As shown in FIG. 6A and FIG. 6B, the second pad 210 with the aforementioned asymmetric design will be displaced after being bonded to the first pad 110 through the first conductive element 300. However, since the width Wb of the portion Pb closer to the first semiconductor die 204 is greater than the width Wc of the portion Pc farther away from the first semiconductor die 204, this pre-compensation design makes the centerline position 210m of the portion Pa of the second pad 210 still quite close to the centerline position 110m of the first pad 110, and the degree of deviation is very small. Therefore, the bonding structure formed by the second pad 210, the first conductive element 300 and the first pad 110 has good stability and can provide stable electrical connection quality.

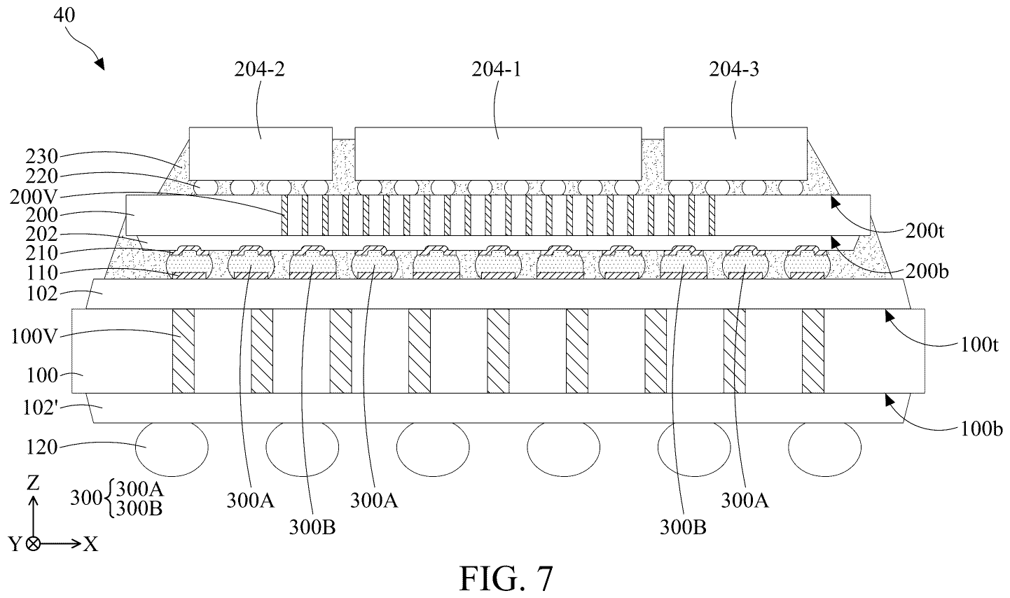

Next, please refer to FIG. 7, which is a cross-sectional diagram of an electronic device 40 in accordance with some embodiments of the present disclosure. It should be understood that, for the sake of clarity, some components of the electronic device 40 may be omitted in the drawings, and only some components are schematically illustrated. In accordance with some embodiments, additional features may be added to the electronic device 40 described below. In accordance with some other embodiments, some features of the electronic device 40 described below may be replaced or omitted. Specifically, FIG. 7 shows a schematic diagram in which the connection structure provided by the embodiment of the present disclosure is further applied to a chip on wafer on substrate (CoWoS) package.

As shown in FIG. 7, the first conductive elements 300 may be disposed between the first circuit layer 102 and the second circuit layer 202. The first conductive elements 300 may be electrically connected to the first pads 110 and the second pads 210 respectively, and the first conductive elements 300 may include the first-type conductive elements 300A and the second-type conductive element 300B having different structural aspects.

Furthermore, the electronic device 40 may include a first semiconductor die 204-1 and a second semiconductor die 204-2. The second semiconductor die 204-2 is adjacent to the first semiconductor die 204-1 and electrically connected to the second circuit layer 202, and the first semiconductor die 204-1 and the second semiconductor die 204-2 are disposed on the second circuit layer 202. As described above, the first semiconductor die 204-1 and the second semiconductor die 204-2 may include a system on chip, a dynamic random access memory, a high bandwidth memory, a photonic integrated circuit, an application specific integrated circuit, or another logic integrated circuit. Moreover, the type of the first semiconductor die 204-1 may be the same as or different from that of the second semiconductor die 204-2. In addition, in accordance with some embodiments, the electronic device 40 may further include a third semiconductor die 204-3 that is the same as or different from the first semiconductor die 204-1 and the second semiconductor die 204-2.

The electronic device 40 may further include a base layer 200 and a first circuit (not illustrated). The first circuit (not illustrated) may be disposed on a first side 200t of the base layer 200 and electrically connected to the first semiconductor die 204-1 and the second semiconductor die 204-2. The second circuit layer 202 may be disposed on a second side 200b of the base layer 200 and electrically connected to the second pads 210. Furthermore, the first circuit (not illustrated) may be electrically connected to the second circuit layer 202 through a via 200V in the base layer 200. The base layer 200 may serve as an interposer. In accordance with some embodiments, the base layer 200 may include silicon wafer, quartz, glass, sapphire, or ceramic, but it is not limited thereto.

In accordance with some embodiments, the electronic device 40 may further include second conductive elements 220. The first semiconductor die 204-1, the second semiconductor die 204-2 and the third semiconductor die 204-3 may be electrically connected to the via 200V in the base layer 200 through the second conductive elements 220, and then electrically connected to the second circuit layer 202. In accordance with some embodiments, the second conductive element 220 may include tin, silver, lead-free tin, copper, nickel, gold, another suitable material or a combination thereof, but it is not limited thereto. In accordance with some embodiments, the first semiconductor die 204-1, the second semiconductor die 204-2, and the third semiconductor die 204-3 may be bonded to the base layer 200 by a reflow process, a fusion bonding process, a hybrid bonding process, a metal-to-metal bonding process, another suitable method, or a combination thereof.

In accordance with some embodiments, the electronic device 40 may further include an insulating layer 230. The insulating layer 230 may surround the first semiconductor die 204-1, the second semiconductor die 204-2 and the third semiconductor die 204-3, and the insulating layer 230 may also contact the second conductive elements 220, the base layer 200, the second circuit layer 202, the first conductive elements 300 and the first circuit layer 102. The insulating layer 230 may be an encapsulating material or an underfill, but it is not limited thereto. In accordance with some embodiments, the insulating layer 230 may include a molding compound, an epoxy resin, another suitable encapsulating material, or a combination thereof, but it is not limited thereto. Furthermore, the insulating layer 230 may include filling particles, such as silicon oxide, aluminum oxide, titanium oxide, zirconium oxide, silicon carbide, graphene, carbon nanotubes, another suitable material, or a combination thereof, but it is not limited thereto.

In addition, in accordance with some embodiments, the electronic device 40 may further include a third circuit layer 102′, and the first circuit layer 102 and the third circuit layer 102′ are disposed on opposite sides of the substrate 100. In detail, the first circuit layer 102 may be disposed on the top surface 100t of the substrate 100, and the third circuit layer 102′ may be disposed on the bottom surface 100b of the substrate 100. Furthermore, the substrate 100 may include glass, and the first circuit layer 102 may be electrically connected to the third circuit layer 102′ through a via 100V in the glass. In other words, in this embodiment, the substrate 100 may have a through glass via (TGV) structure. In accordance with some embodiments, the electronic device 40 may further include third conductive elements 120, and the third circuit layer 102′ may be electrically connected to the third conductive elements 120, so that the electronic device 40 can be further electrically connected to other external electronic components.

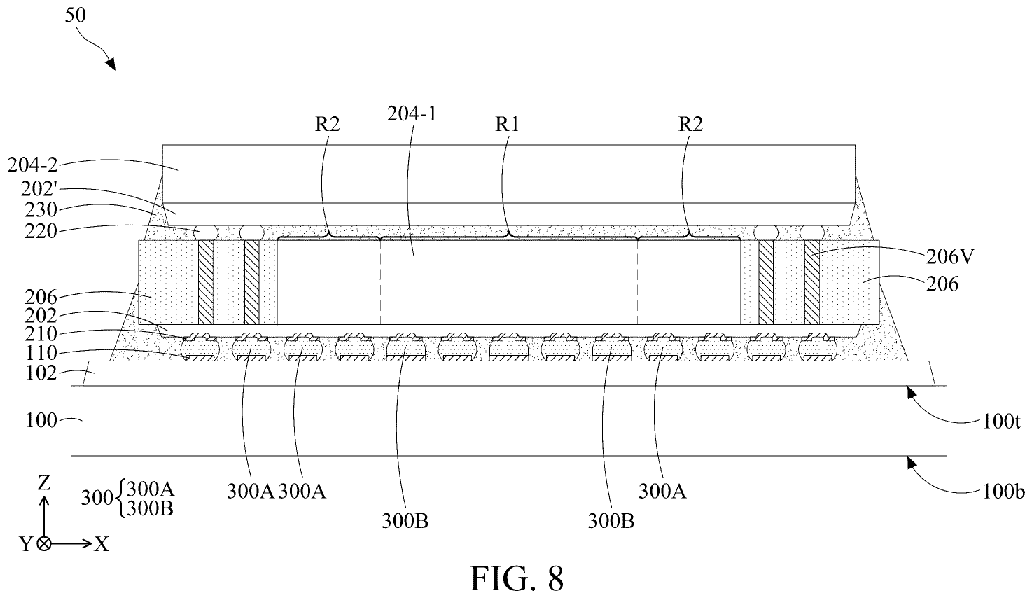

Please refer to FIG. 8, which is a cross-sectional diagram of an electronic device 50 in accordance with some embodiments of the present disclosure. It should be understood that, for the sake of clarity, some components of the electronic device 50 may be omitted in the drawings, and only some components are schematically illustrated. In accordance with some embodiments, additional features may be added to the electronic device 50 described below. In accordance with some other embodiments, some features of the electronic device 50 described below may be replaced or omitted. Specifically, FIG. 8 shows a schematic diagram in which the connection structure provided by the embodiment of the present disclosure is further applied to a structure similar to integrated fan-out package on package (InFO—PoP).

As shown in FIG. 8, the first conductive elements 300 may be disposed between the first circuit layer 102 and the second circuit layer 202. The first conductive elements 300 may be electrically connected to the first pads 110 and the second pads 210 respectively, and the first conductive elements 300 may include the first-type conductive elements 300A and the second-type conductive elements 300B having different structural aspects. Under the main region R1, at least parts of the first-type conductive elements 300A and the second-type conductive elements 300B are arranged alternately.

Furthermore, the electronic device 50 may include the first semiconductor die 204-1 and the second semiconductor die 204-2. The second semiconductor die 204-2 may be disposed on the first semiconductor die 204-1, and the second semiconductor die may be electrically connected to the second circuit layer 202 through a via 206V located in the encapsulating layer 206.

In accordance with some embodiments, the electronic device 50 may further include a fourth circuit layer 202′ and the second conductive elements 220. The fourth circuit layer 202′ may be disposed between the second semiconductor die 204-2 and the first semiconductor die 204-1, and the fourth circuit layer 202′ may be electrically connected to the via 206V in the encapsulating layer 206 through the second conductive elements 220, and then electrically connected to the second circuit layer 202.

In accordance with some embodiments, the electronic device 50 may further include the insulating layer 230. The insulating layer 230 may surround the second semiconductor die 204-2, and the insulating layer 230 may also be in contact with the fourth circuit layer 202′, the second conductive element 220, the first semiconductor die 204-1, the encapsulating layer 206, the second circuit layer 202, the first conductive elements 300 and the first circuit layer 102.

In addition, in accordance with some embodiments, the electronic device 50 may further include the third circuit layer 102′ (as shown in FIG. 7), and the first circuit layer 102 and the third circuit layer 102′ may be disposed on opposite sides of the substrate 100. In detail, the first circuit layer 102 may be disposed on the top surface 100t of the substrate 100, and the third circuit layer 102′ may be disposed on the bottom surface 100b of the substrate 100. Furthermore, the substrate 100 may include glass, and the first circuit layer 102 may be electrically connected to the third circuit layer 102′ through a via in the glass (as shown in FIG. 7). In other words, in this embodiment, the substrate 100 may have a through glass via (TGV) structure.

To summarize the above, according to the embodiments of the present disclosure, the provided electronic device includes a connection structure configured in a specific manner (for example, including first-type conductive elements and second-type conductive elements disposed between circuit layers). With the combination and configuration of conductive elements with different structural types, the connection structure can have the dual functions of absorbing stress and resisting stress, thereby alleviating problems such as peeling, breaking, or excessive displacement or deformation of the connection structure. The structural strength and reliability of the electronic device therefore can be improved.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Thus, the appended claims are intended to include within their scope such processes, machines, manufacture, compositions of matter, means, methods or steps. Moreover, each claim constitutes an individual embodiment, and the claimed scope of the present disclosure includes the combinations of the claims and embodiments. The scope of protection of the present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a substrate;
a first circuit layer disposed on the substrate and comprising a plurality of first pads;
a first semiconductor die disposed on the first circuit layer;
a second circuit layer electrically connected to the first semiconductor die and disposed between the first circuit layer and the first semiconductor die, and comprising a plurality of second pads; and
a plurality of first conductive elements disposed between the first circuit layer and the second circuit layer, each of the plurality of first conductive elements electrically connecting to one of the plurality of first pads and one of the plurality of second pads, and comprising a first portion adjacent to one of the plurality of first pads, a second portion adjacent to one of the plurality of second pads, and a middle portion between the first portion and the second portion,
wherein the plurality of first conductive elements comprise a plurality of first-type conductive elements and a plurality of second-type conductive elements, each of the plurality of first-type conductive elements has a maximum width at the middle portion and each of the plurality of second-type conductive elements has a maximum width at the first portion.

2. The electronic device according to claim 1, wherein the maximum width of each of the plurality of second-type conductive elements is located at an interface between the first portion and the one of the plurality of first pads.

3. The electronic device according to claim 1, wherein the first semiconductor die has a main region and an edge region, wherein the plurality of first-type conductive elements and the plurality of second-type conductive elements are arranged alternatively under the main region.

4. The electronic device according to claim 1, wherein the first semiconductor die has a main region and an edge region, and a ratio of a number of the plurality of first-type conductive elements to a number of the plurality of second-type conductive elements is greater than or equal to 1 and less than or equal to 5 under the main region.

5. The electronic device according to claim 1, wherein one of the plurality of first-type conductive elements is in contact with a side surface of one of the plurality of first pads.

6. The electronic device according to claim 1, wherein one of the plurality of first pads has a top surface and a bottom surface opposite to the top surface, and a roughness of the bottom surface is greater than a roughness of the top surface.

7. The electronic device according to claim 1, further comprising an encapsulating layer surrounding the first semiconductor die, wherein one of the plurality of second pads is overlapped with the encapsulating layer.

8. The electronic device according to claim 7, wherein in a cross-sectional diagram, the one of the plurality of second pads has a first portion in contact with a conductive layer of the second circuit layer, a second portion connected to a side of the first portion adjacent to the first semiconductor die and a third portion connected to another side of the first portion away from the first semiconductor die, and a first width of the second portion is greater than a second width of the third portion.

9. The electronic device according to claim 8, wherein a ratio of the second width to the first width is greater than or equal to 0.6 and less than or equal to 0.9.

10. The electronic device according to claim 7, further comprising a second semiconductor die disposed on the first semiconductor die, wherein the second semiconductor die is electrically connected to the second circuit layer through a via in the encapsulating layer.

11. The electronic device according to claim 1, further comprising a third circuit layer, wherein the first circuit layer and the third circuit layer are disposed on two opposite sides of the substrate, the substrate comprises glass, and the first circuit layer is electrically connected to the third circuit layer through a via in the glass.

12. The electronic device according to claim 1, further comprising a second semiconductor die disposed adjacent to the first semiconductor die and electrically connected to the second circuit layer, wherein the first semiconductor die and the second semiconductor die are disposed on the second circuit layer.

13. The electronic device according to claim 12, further comprising:
a base layer; and
a first circuit disposed at a first side of the base layer and electrically connected to the first semiconductor die and the second semiconductor die,
wherein the second circuit is disposed at a second side of the base layer, and the first circuit is electrically connected to the second circuit layer through a via in the base layer.

14. The electronic device according to claim 12, further comprising a third circuit layer, wherein the first circuit layer and the third circuit layer are disposed on two opposite sides of the substrate, the substrate comprises glass, and the first circuit layer is electrically connected to the third circuit layer through a via in the glass.

15. The electronic device according to claim 1, further comprising:
an encapsulating layer surrounding the first semiconductor die, wherein one of the plurality of second pads is overlapped with the first semiconductor die.

16. The electronic device according to claim 15, wherein in a cross-sectional diagram, one of the plurality of second pads comprises:
a first portion in contact with a conductive layer of the second circuit layer;
a second portion connected to a side of the first portion; and
a third portion connected to another side of the first portion, and a ratio of a width of the second portion to a width of the third portion is greater than or equal to 0.9 and less than or equal to 1.1.

17. The electronic device according to claim 1, wherein one of the plurality of first-type conductive elements contacts one of the plurality of first pads and one of the plurality of second pads, the one of the plurality of first pads has a first width, the one of the plurality of second pads has a second width, one of the plurality of second-type conductive elements contacts another one of the plurality of first pads and another one of the plurality of second pads, the another one of the plurality of first contact pads has a third width, the another one of the plurality of second contact pads has a fourth width, and a ratio of the first width to the second width is smaller than a ratio of the third width to the fourth width.

18. The electronic device according to claim 17, wherein the ratio of the first width to the second width is greater than or equal to 0.7 and less than or equal to 1.2.

19. The electronic device according to claim 17, wherein the ratio of the third width to the fourth width is greater than or equal to 1.3 and less than or equal to 3.

20. The electronic device according to claim 17, wherein the first width is smaller than the third width.
